(19) United States
(12) Patent Application Publication
(10) Pub. No.: US 2019/0296206 A1
(43) Pub. Date: Sep. 26, 2019

(54) Personal Environmental Control System

(71) Applicant: Platum Technologies LLC, Missoula, MT (US)

(72) Inventors: Dylan Kemp, Missoula, MT (US); Cameron Brown, Missoula, MT (US)

(73) Assignee: Platum Technologies LLC, Missoula, MT (US)

(21) Appl. No.: 16/359,377

(22) Filed: Mar. 20, 2019

Related U.S. Application Data
(60) Provisional application No. 62/645,655, filed on Mar. 20, 2018.

(51) Int. Cl. H01L 35/32; F25B 21/02

(52) U.S. Cl. CPC H01L 35/32; F25B 2321/025; F25B 2321/023; F25B 21/02

(57) ABSTRACT

The current disclosure relates to a personal environmental control system that regulates the temperature in immediate area of the system, which can be attached to a garment and worn by a person, animal, or device that requires temperature control. In one embodiment of the personal environmental control system, temperature is controlled through the use of a heat transfer unit including at least one Peltier unit and at least two closed loops carrying fluid for transferring heat away from the garment.

### CROSS-REFERENCE TO RELATED APPLICATIONS

This application claims the priority, under § 119, of copending U.S. Provisional Patent Application No. 62/645,655, filed on Mar. 20, 2018; the prior application is herewith incorporated by reference herein in its entirety.

### BACKGROUND OF THE INVENTION

Individuals often require more control over their personal environment than room or building environmental control systems provide. For example, a person may need to wear protective gear, dance outfits, or costume clothing which greatly increases or decreases their body temperature. The system described here, a personal environmental control system, can be used to provide better control over a person's immediate environment (their body and clothing). Such a system can be, for example, embedded in a wearable garment such as a vest or a coat.

### SUMMARY OF THE INVENTION

The personal environmental control system claimed here includes at least two hollow tubes, liquid able to flow through the tubes, devices for circulating the liquid through the tubes, temperature control unit for altering the temperature of the liquid flowing through tubes, and a power supply for the pumps and the temperature control. The liquid flowing through the tubes then circulates through an individual's personal environment and can alter the temperatures of the personal environment. As liquid flows through the temperature control unit heat can be transferred from one tube to at least one other tube and thus alter the temperature of the liquid to control the temperature of a personal environment.

### BRIEF DESCRIPTION OF THE DRAWINGS

The foregoing aspects and other features of the disclosure are explained in the following description, taken in connection with the accompanying drawings, herein:

FIG. 1 shows a schematic of one embodiment of the personal environmental control system.

FIG. 2 is a schematic of an example embodiment of the heat transfer unit assembled.

FIG. 3 presents the schematic shown in FIG. 2 of an example embodiment of the heat transfer unit unassembled to better illustrate the individual parts.

FIG. 4 shows an example embodiment of a cooling block which forms a part of heat transfer unit in the personal environmental control system.

FIG. 5 shows an example embodiment of heat transfer device which forms a part of the personal environmental control system.

### DETAILED DESCRIPTION OF THE EMBODIMENTS

The system described herein comprises at least two closed loops which may consist of hollow tubes wherein liquid in said tubes is used to transfer heat between the at least two loops. The transfer of heat may occur in between loops by changing the direction of heat transfer through said tubes which comprise the loops, using the electrically controlled Peltier element(s) to transfer heat between the closed loops. In addition, a loop containing a liquid is capable of transferring heat through the loop without interacting with other loops and therefore may be independent from other loop or loops. Such liquid may, for example, be water or another liquid with heat conducting properties. Heat transfer between two loops may occur in some embodiments in a controlled fashion utilizing a thermal electric device which may be controlled by an electric device capable of directing the flow of heat in multiple directions in a controlled fashion.

Alternatively, in other embodiments, the system may consist of loops comprised of a static medium, such a heat pipe, which transfers heat in at least one direction rather than using a liquid to transfer heat through the tube. In some embodiments at least one loop is used to regulate the flow of heat to or from one area of the loop while at least one loop is used to transport heat to or from the outside environment which may be in close proximity of the system.

More specifically, the system consists of a heat regulating closed loop and a second heat transfer closed loop. The heat regulating closed loop consisting of hollow heat conductive tubing with a liquid inside (i.e. water) to allow for efficient heat transfer of heat to and from the heat regulating closed loop. The transfer may be a bidirectional transfer, namely transfer of the heat from the system to the external environment or to the system from the external environment. This bi-directional flow controls the area around the person wearing a garment to which the system is connected. The liquid inside the tubing is circulated in a closed loop by a pump, which may be an electric pump in some embodiments of the system.

The hollow tubing could be comprised or constructed from heat conductive elements, compounds, or materials, for example copper or brass, and may be connected in some embodiments to flexible portions of the tube made of different elements, compounds, or materials to make the regulated closed loop more flexible and to allow the wearer of a pieces of clothing to which the personal environmental control system is attached to move more freely. One of the closed loops may include a multiple sections, for example a first and a second section, wherein the second section may contain a heat transfer device in order to have one section of the tube be heat delivering and one section of the tube to be heat transfer.

In some embodiments, the heat transfer closed loop may be integrated with or attached to a second closed loop that performs heat regulating separate from the heat regulating closed loop. The heat transfer closed loop may consist of tubing made from non-conductive material that is connected to a second cooling block that may be part of the heat transfer unit, connected to an electric pump, and connected to a heat transfer component such as a radiator with a fan. A liquid (i.e. water or coolant) circulates within the heat transfer closed loop. In alternative embodiments, the loop may use a heat conducting solid pipe which may not contain liquid but instead be comprised of heat conducting elements, compounds, or materials that transfer heat through the pipe.

In some embodiments, the heat transfer unit may be comprised of two blocks, one for the heat regulating closed loop, and one for the heat transfer closed loop, with at least one Peltier unit with a lubricant placed between the two blocks. In some embodiments the lubricant may be a thermal grease placed between the surfaces of the Peltier units and the blocks. The at least one Peltier element(s) may be powered by a source, such as an electric power source, capable of precisely controlling the power to the at least one Peltier element(s). The heat transfer unit is capable of both controlling the immediate environment by either cooling or heating the heat controlling closed loop or the heat transfer closed loop in contact with the heat transfer unit by altering the polarity of the at least one Peltier elements.

The regulated closed loop may be fitted to the inside of a garment to be concealed and to allow for easy donning of the garment in which the system is placed. The heat transfer closed loop fitted on the outside of the garment to allow ambient air to flow through the radiator using the fan. Because part of the exhaust side is connected to regulator core (namely the cooling block), flexible tubing transitions from inside the garment to the outside.

The heat transfer unit responsible for regulating the flow of heat between the two loops may be a thermoelectric device controlled by a control board electrically connected to the Peltier elements, wherein the Peltier elements may attach to or be placed between two heat controlling blocks. In one embodiment Peltier elements may be placed between two or more blocks, each block circulating liquid from one of the closed loops through one side of heat transfer unit. In still other embodiments, heat pipes may be used with generic heat conductive metal blocks to alter or control heat and\or cooling.

The Figures show one embodiment of the personal environmental control system and how the personal environmental control system can be integrated into a garment, in this case a vest style garment. The vest style embodiment shows the hollow tubes placed in the vest including the back and front of the vest. The embodiment shown includes a “plate carrier” style unit which consists of two large rectangular pouch-like pieces of fabric, one on the front, and one on the back, that houses the heat regulating closed loop of the personal environmental control system. Flexible tubing connects to front side and the back side to complete the heat regulating closed loop. Someone skilled in the art of heating and cooling systems will recognize these two embodiments are merely examples of embedding the system in a garment and that many additional embodiments of the system at varying scales and in many configurations are possible. For example, the flexible tubing connecting front and back can either be worn over the shoulders, or under the arms, depending on the preference of the wearer.

The components of the personal environmental control system may be constructed as a single fixed part system or the system may be formed by detachable, interchangeable parts, including all parts claimed and unclaimed. For example, the heat dissipation closed loop may include a radiator with a fan wherein the radiator may be detachable when the tubes leading to the radiator have couplers that permit disconnection. Such couplers allow removal of the radiator and reconnection of the heat dissipation closed unit with another heat dissipation device, or without the radiator or any dissipation device. Detachable components allow more convenient storage, improved serviceability, and the ability to switch to components better suited to heating or cooling performance.

One skilled in the art will readily appreciate that the present invention is well adapted to carry out the objective of controlling a person, animal, or object's immediate environment with the advantages discussed, as well as those inherent therein. The embodiments presented herein are exemplary embodiments and not intended as limitations on the scope, configuration, performance, or functionality of the system claimed below. Changes therein and other uses will occur to those skilled in the art are encompassed within the spirit of the invention as defined by the scope of the claims.

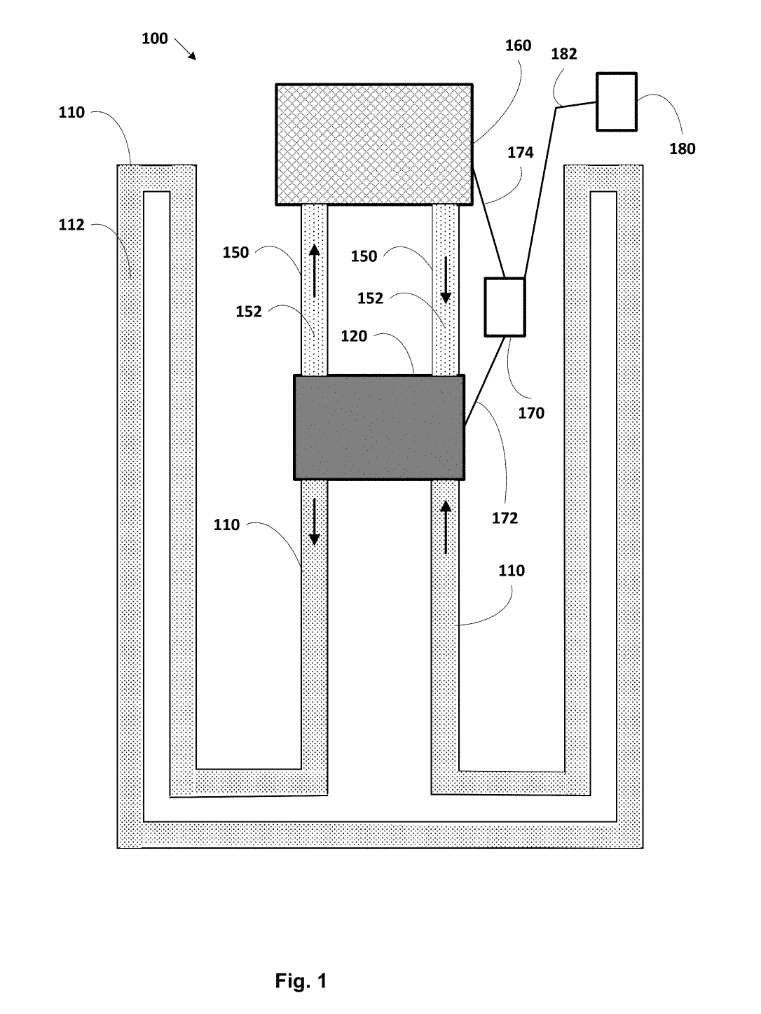

FIG. 1. shows an example embodiment of the personal environmental control system 100. The example embodiment of the personal environmental control system 100 includes a first hollow tube 110 containing a first liquid 112 connected to a heat transfer unit 120, and a second hollow tube 150 containing a second liquid 152 connected to both a heat transfer device 160 and the heat transfer unit 120. The example embodiment of the personal environmental control system 100 includes a power supply 170 connected by electrical connection 172 to the heat transfer unit 120, and connected by an electrical connection 174 to the heat transfer device 160. An electrical current control device 180 is connected by an electrical connection 182 to the power supply 170. The electrical current control device 180 controls the amount of electricity the power supply 170 supplies to the heat transfer unit 120 and to the heat transfer device 160 through signals sent to the power supply 170 through electrical connection 182.

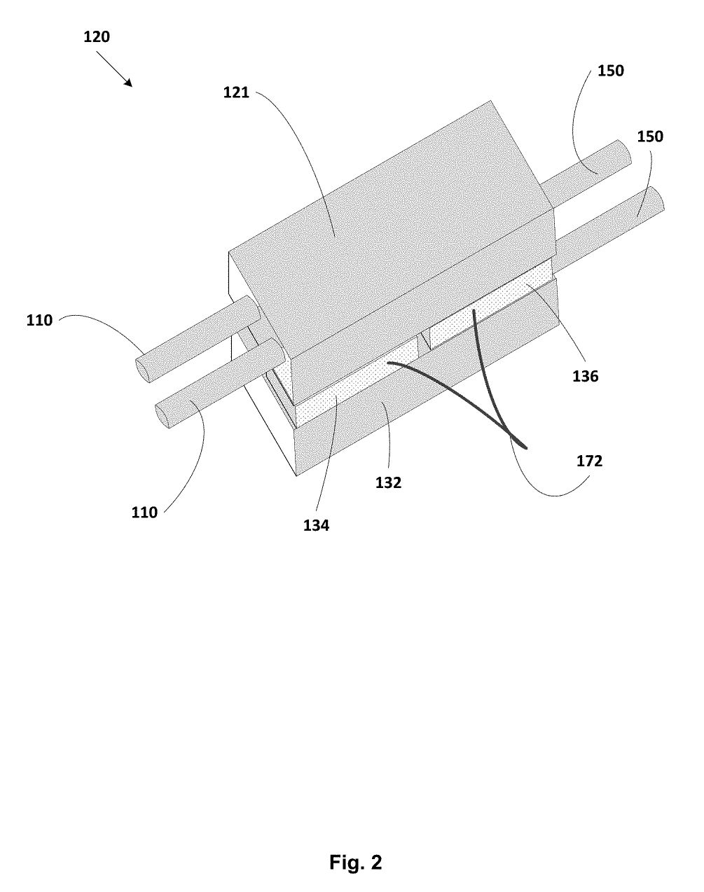

In the example of FIG. 1, the first liquid 112 flows, at least initially, in the direction indicated by the arrows through the first hollow tube 110. When the first liquid 112 flows into the heat transfer unit 120, the first liquid 112 will be routed through the heat transfer unit and back out the first hollow tube 110. During such routing, the first liquid 112 may increase or decrease in temperature, or the temperature may remain unchanged depending upon the flow of electrical current from power supply 170 through electrical connection 172 into the heat transfer unit 120. It should be understood that in some embodiments, the flow of liquid 112 may be in either direction and could alternate flow direction in response to changes in the heat transfer unit 120. More detail on both directional flow of liquid 112 and changes in the temperature of liquid 112 as caused by the heat transfer unit 120 will be explained in FIG. 2.

Continuing with the example of FIG. 1, the second hollow tube 150 contains the second liquid 152 flowing, at least initially, in the direction indicated by the arrows through the second hollow tube 150. When the second liquid 152 flows into the heat transfer unit 120, the second liquid 152 will be routed through the heat transfer unit and back out the second hollow tube 150. During such routing, the second liquid 152 may increase or decrease in temperature, or the temperature may remain unchanged depending upon the flow of electrical current from the power supply 170 through the electrical connection 172 into the heat transfer unit 120. In addition, the second liquid 152 flows through the second hollow tube 150 into and back out of the heat transfer device 160 where the temperature of second liquid 152 may increase, decrease, or remain the same depending on the state of the heat transfer device 160, where the state may be transfer heat from the second liquid 152 in the second hollow tube 150 into the environment or transferring heat from the environment into the second liquid 152 in the second hollow tube 150. The power supply 170 supplies electrical current through the electrical connection 174 to the heat transfer device 160 to control the state of the heat transfer device 160 and the impact on the temperature of the second liquid 152. It should be understood that, in some embodiments, the second liquid 152 may flow in either direction or switch the direction of flow without effecting the ability of the heat transfer device 160 to alter the temperature of the second liquid 152.

The example embodiment in FIG. 1 can control the personal environment around the personal environmental control system 100 by, for example, transferring heat from the first closed system to the second closed system by transferring heat to the second closed system as first liquid 112 and second liquid 152 flow through the heat transfer unit 120. Second liquid 152 then flows through the heat dissipation device where heat absorbed from first liquid 112 through the heat transfer unit 120 is dissipated into the environment. This allows first liquid 112 to cool the personal environment around the personal environmental control system 100 by absorbing heat into the first liquid 112, transferring to second liquid 152, and then transferring heat away from the personal environment.

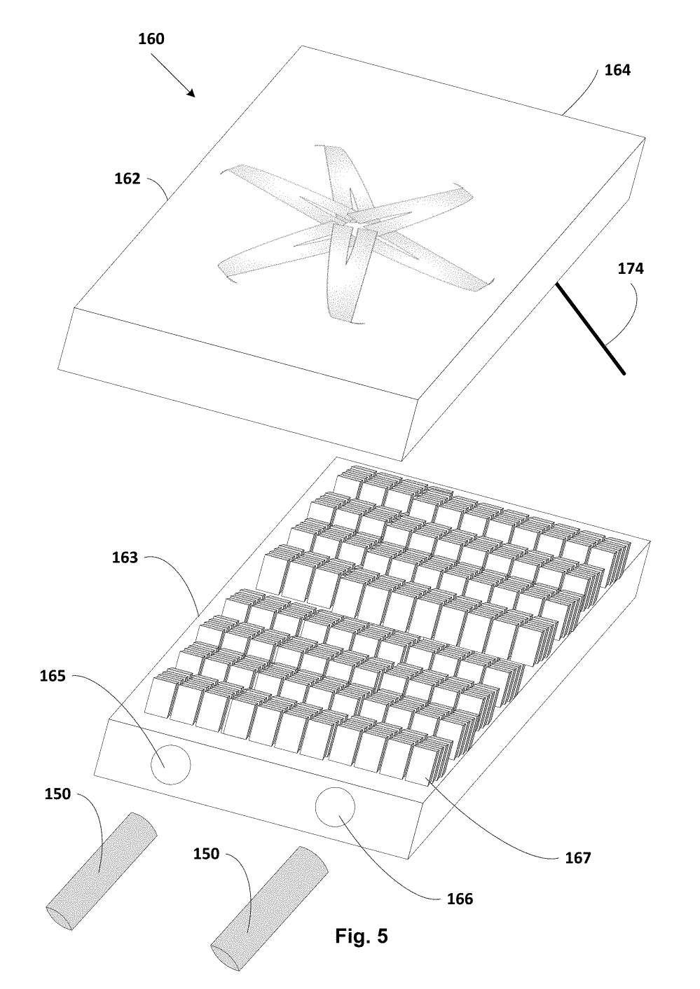

FIG. 2 shows and example embodiment of the heat transfer unit 120 in more detail. The heat transfer unit 120 includes a first cooling block 121 and a second cooling block 132, wherein a first Peltier unit 134 and a second Peltier unit 136 are placed between the first cooling block 121 and the second cooling block 132. The electrical connection 172 splits and connects to both the first Peltier unit 124 and the second Peltier unit 126. First liquid 112 flows through the first hollow tube 110 into the first cooling block 121 and then back out of the first cooling block 121 into the first hollow tube 110. Second liquid 152 similarly flows through the second hollow tube 150 into the second cooling block 132 and then back out of the second cooling block 132 into the second hollow tube 150. Application of electrical current to the first Peltier unit 124 and the second Peltier unit 126 cause heat to be transferred from the first liquid 112, flowing through the first cooling block 121, to the second cooling block 132. The heat transferred to the second cooling block 132 heats the second liquid 152 which flows through and out of the second cooling block through the second hollow tube 150. This heat transfer from first liquid 112 to second liquid 152 cools first liquid 112 and therefore cools, or at least reduces the temperature, of first liquid 112 as it flows through the closed loop formed by the first hollow tube 110. This decrease in temperature cools the environment around the personal environmental control system 100. The heat transferred to second liquid 152 will increase the second liquid 152 temperature which will be dissipated as shown in FIG. 5 and described below.

Alternatively, the personal environmental control system 100 can transfer heat in the opposite direction, namely increasing the temperature of the first liquid 112 flowing through the first hollow tube 110 to heat the area around the personal environmental control system 100. In this example of heat transfer, the embodiment of the heat transfer unit 120 shown in FIG. 2 transfers heat from the environment around the ambient heat transfer device 160 into the second liquid 152 flowing through the second hollow tube 150 into the second cooling block 132. The heat from the second liquid 152 which flows through the second hollow tube 150 into and out of the second cooling block 132 is transferred to the first fluid 112 flowing through the first hollow tube 110. The transferred heat increases the temperature of the first fluid 112 and thus increases the temperature of the area around the personal environmental control system 100. This second flow of heat allows the personal environmental control system 100 to increase the temperature around the personal environmental control system 100 while the flow of heat described previously, from the first fluid 112 to the second fluid 152 decreases the temperature around the personal environmental control system 100. One skilled in the art can observe this bi-directional heat flow can control the temperature around the personal environmental control system 100 by increasing or decreasing the temperature of the first fluid 112.

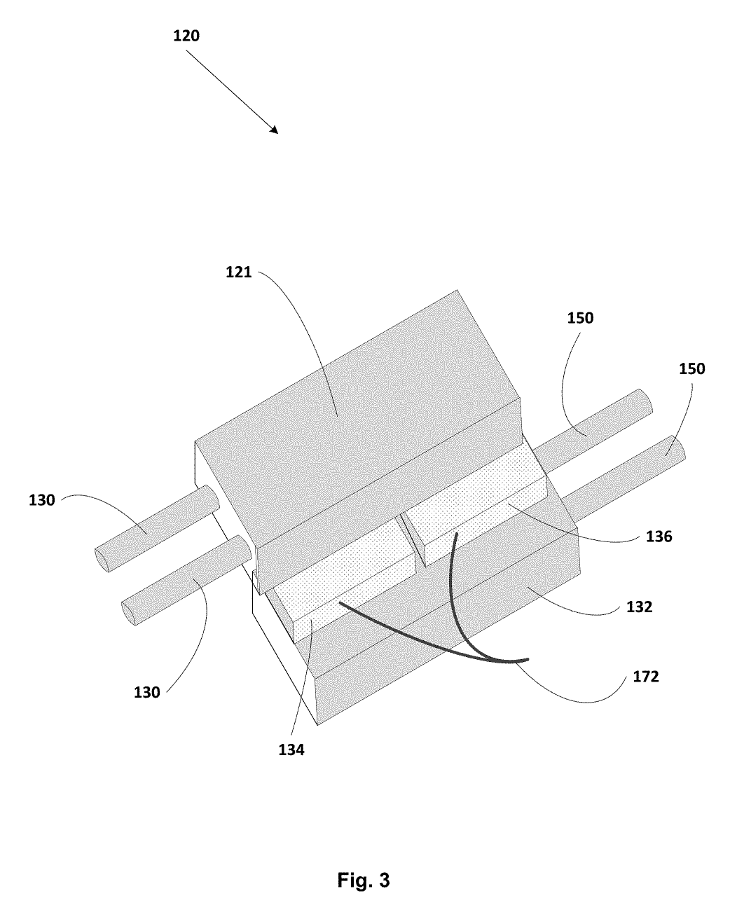

FIG. 3 shows an exploded view of the heat transfer unit 120, wherein the first cooling block 121 and the second cooling block 132 are connected to opposite sides of the first Peltier unit 134 and second Peltier unit 136. It can also be seen in FIG. 3 that the first liquid 112 flows into and out of only cooling block 121 while second liquid 152 flows into and back out of cooling block 132, only. The liquids in this embodiment do not mix but rather transfer heat in reaction to the functions of first Peltier unit 134 and second Peltier unit 136. One skilled in the art will recognize the electrical connection 182 may connect to the first Peltier unit 134 and second Peltier unit 136 in parallel, as shown in FIG. 3, or in serial, or in another configuration, and the split or join of the electrical connection 182 may occur prior to connecting to the heat transfer unit 120 or within a casing or housing of the heat transfer unit 120 (no casing or housing shown in FIG. 3.).

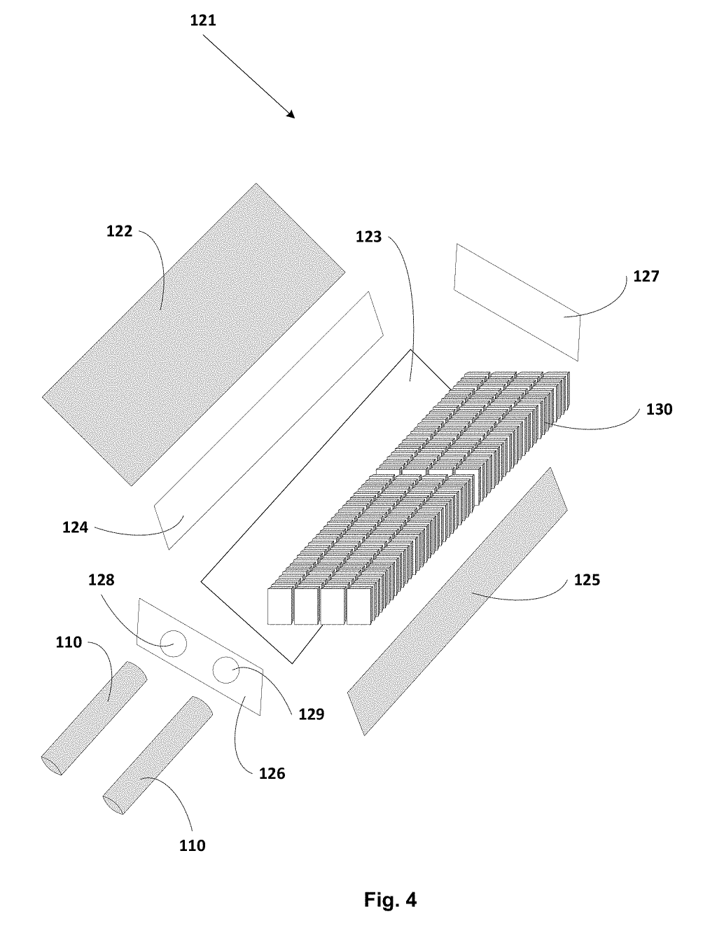

FIG. 4 shows an exploded view of the example embodiment of the heat transfer unit 120, specifically the first cooling block 121. In this exploded view, the first cooling block 121 includes a top cover 122, a bottom cover 123, a first side cover 124, a second side cover 125, a front cover 126 and back cover 127. The front cover 125 includes a first hole 128 and a second hole 129 both of which connection to the first hollow tube 110 through. The cooling block 121 includes a radiator 127 which permits the first liquid 112 to circulate through the first cooling block 121. Also shown in this example embodiment is a set of fins 130 through which heat from the first liquid 112 is transferred from the first liquid 112. The heat transferred from the first liquid 112 into the set of fins 130 is then transferred to the second cooling block 132. One skilled in the art will recognize the second cooling block may be composed of a similar set of fins as shown in FIG. 4 which may be enclosed in a housing similar to that shown in FIG. 4, or may be composed of an entirely different heat transfer technology to transfer heat to the second liquid 152.

FIG. 4 shows an example embodiment of the heat transfer unit 120 wherein the heat absorbed from the local environment into the first liquid 112 as it circulates through the first hollow tube enters the first cooling block 121. The first liquid 112 flowing through the first cooling block 121 flows around the set of fins 130 and as doing so transfers heat from the first liquid 112 to the set of fins 130. The set of fins 130 increase in temperature and the first Peltier unit 134 and second Peltier unit 136 causes the heat absorbed in the set of fins 130 to be transferred to the second cooling block 132. The second cooling block 132 increases the temperature of the second liquid 152 which flows to the heat transfer device 160 in order to dissipate the transferred heat into the environment.

FIG. 5 shows an example embodiment of the heat transfer device 160 shown in FIG. 1. The heat transfer device 160 in this example embodiment includes a first molding 162, a second molding 163, a fan 164, a first tube connector 165, a second tube connector 166, and set of fins 167. The heat transfer device 160 receives electrical current through electrical connection 174. The second liquid 152 (not shown in FIG. 5) flows through the second hollow tube 150 from the heat transfer unit 120, as described previously, and into the heat transfer device 160, specifically into the second molding 163 and circulates through the set of fins 167 within the first molding 163. The fan 164 rotates causing air to move through the heat transfer device 160, specifically through the first molding 162 and through the second molding 163, around the set of fins 167. The heat from the second liquid 152 transfers to the air moving through the heat transfer device which cools the second liquid 152. This transfer completes the transfer of heat from the first liquid 112 to the second liquid 152 and then away from the personal environmental control system 100 into the air thus controlling the personal environment around the personal environmental control system 100. Alternatively, if personal environmental control system 100 is set to heat the first liquid 112, the heat from the air transfers to the second liquid 152 increasing the temperature of the second liquid 152. As the second liquid 152 flows into the heat transfer unit 120 wherein the temperature of the first liquid 112 is increased.

In this example embodiment of the personal environmental control system 100, the heat transfer unit 120 and the heat dissipation device 160 transfer heat from the first liquid 112 to the second liquid 152 and then transfers heat into the air to cool the personal environment around the personal environmental control system 100. It should be recognized that the heat dissipation device could be different from that shown in this embodiment. For example, the first liquid 112 could circulate around the second hollow tube within the heat transfer unit 120 to transfer heat from the first liquid 112 to the second liquid 152. In yet another embodiment the heat transfer device 160 could contain yet a third liquid that would absorb heat and dissipate such heat through circulation outside the personal environment of the personal environmental control system 100.

What is claimed is:

1. A personal environmental control system, the system comprising:
a heat transfer unit comprising:
a first cooling block;
a second cooling block;
at least one Peltier unit;
a first closed loop comprising:
a first hollow tube;
the first cooling block of the heat transfer unit; and
a first liquid capable of flowing through the first closed loop;
a second closed loop comprising:
a second hollow tube;
the second cooling block of the heat transfer unit;
an ambient heat transfer device;
a second liquid capable of flowing through the second loop; and
a power supply in electrical communication with the at least one Peltier unit and the ambient heat transfer device; and
an electrical current control device connected to the power supply.

2. The personal environmental control system of claim 1 wherein the first cooling unit is connected to a first side of the at least one Peltier unit and the second cooling unit is connected to a second side of the at least one Peltier unit opposite the first side of the Peltier unit.

3. The personal environmental control system of claim 2 wherein a supply of electric current from the power supply to the at least one Peltier device causes one side of the heat transfer unit to be warm and an opposite side to be cool.

4. The personal environmental control system of claim 1 wherein the personal environmental control system is attached to an article of clothing.

5. The personal environmental control system of claim 4 wherein the article of clothing is selected from the group consisting of a shirt, vest, sweatshirt, pants, and coat.

6. The personal environmental control system of claim 1 wherein the first liquid may flow in either direction through the first closed loop.

7. The personal environmental control system of claim 1 wherein the second liquid may flow in either direction through the second closed loop.

8. The personal environmental control system of claim 1 wherein the electrical current control device generates signal for controlling the flow of electricity from the power supply to the heat transfer unit.

9. The personal environmental control system of claim 1 further comprising a heat dissipation device attached to at least one of the first hollow tube or the second hollow tube wherein the heat dissipation device transfers heat away from the area around the personal environmental control system.

10. The personal environmental control system of claim 9 wherein the heat dissipation device is selected from the group consisting of a fan, a radiator with a fan, a heat absorbing device, and a heat absorbing material.

11. The personal environmental control system of claim 1 wherein the electrical current control device regulates the temperature of the liquid in at least one of the first closed loop or the second closed loop by generating signals to the power supply to alter the flow of electricity to the heat transfer unit.

12. The personal environmental control system of claim 1 wherein heat is dissipated from the second closed loop by the second liquid flowing through the ambient heat transfer device.

13. The personal environmental control system of claim 1 wherein the first hollow tube is comprised of a material that conducts heat.

14. The personal environmental control system of claim 1 wherein the second hollow tube is comprised of a material that does not conduct heat.

15. The personal environmental control system of claim 1 wherein the first hollow tube is comprised of a material that is flexible.

16. The personal environmental control system of claim 1 wherein the second hollow tube is comprised of a material that is flexible.

17. The personal environmental control system of claim 1, wherein the first cooling block comprises a plurality of heat dissipating fins.

18. The personal environmental control system of claim 1, wherein the second cooling block comprises a plurality of heat dissipating fins.
